(19) United States
(12) Patent Application Publication
(10) Pub. No.: US 2022/0057997 A1
(43) Pub. Date: Feb. 24, 2022

(54) COMPUTING ACCELERATION FRAMEWORK

(71) Applicant: SoftIron Limited, Chilworth (GB)

(72) Inventors: Lionel Corbet, Milpitas, CA (US); Harry Richardson, Lamarsh (GB)

(73) Assignee: Softiron Limited, Chilworth (GB)

(21) Appl. No.: 16/931,752

(22) Filed: Jul. 17, 2020

(51) Int. Cl. G06F 7/72; G06F 15/78

(52) U.S. Cl. CPC G06F 7/724; G06F 15/7896

(57) ABSTRACT

A processing acceleration system including at least one gate array that performs finite field arithmetic and at least one controller that sends information to the gate array(s) upon a determination that sending the information, performing the finite field arithmetic by the gate array(s), and sending results of the finite field arithmetic to at least one destination is more efficient than general-purpose computing processor(s) performing the finite field arithmetic and sending the results to the at least one destination. The gate array(s) may include field programmable gate array(s), and the destination(s) may include the general-purpose computing processor(s) or storage devices. The finite field arithmetic may include galois field arithmetic such as modular arithmetic, for example as may be used with respect to erasure coding for storage device(s).

### CROSS-REFERENCE TO RELATED APPLICATION

Not applicable

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### BACKGROUND

The present disclosure generally relates to a processing acceleration framework or frameworks using one or more gate arrays, for example field programmable gate arrays.

### SUMMARY

Briefly, aspects of the subject technology include a processing acceleration system including at least one gate array that performs finite field arithmetic and at least one controller that sends information to the gate array(s) upon a determination that sending the information, performing the finite field arithmetic by the gate array(s), and sending results of the finite field arithmetic to at least one destination is more efficient than general-purpose computing processor(s) performing the finite field arithmetic and sending the results to the at least one destination. The gate array(s) may include field programmable gate array(s), and the destination(s) may include the general-purpose computing processor(s) or storage devices. The finite field arithmetic may include galois field arithmetic such as modular arithmetic, for example as may be used with respect to erasure coding for storage device(s).

The controller(s) may be part of or separate from the general-purpose computing processor(s) or the gate array(s). The processing acceleration system may include the general-purpose computing processor(s).

The subject technology also includes associated methods.

This brief summary has been provided so that the nature of the invention may be understood quickly. Additional steps or different steps than those set forth in this summary may be used. A more complete understanding of the invention may be obtained by reference to the following description in connection with the attached drawings.

### BRIEF DESCRIPTION OF THE DRAWINGS

FIG. 1 illustrates a processing acceleration system according to aspects of the subject technology.

FIG. 2 illustrates that controller(s) used by aspects of the processing acceleration system may be included in general-purpose computing processor(s).

FIG. 3 illustrates that controller(s) used by aspects of the processing acceleration system may be included in gate array(s).

FIG. 4 illustrates aspects of a method that may be used by a processing acceleration system according to aspects of the subject technology.

### DETAILED DESCRIPTION

Briefly, aspects of a processing acceleration framework according to the subject technology include a processing acceleration system. The system preferably includes at least one gate array that performs finite field arithmetic and at least one controller that sends information to the gate array(s) upon a determination that sending the information, performing the finite field arithmetic by the gate array(s), and sending results of the finite field arithmetic to at least one destination is more efficient than general-purpose computing processor(s) performing the finite field arithmetic and sending the results to the at least one destination. The gate array(s) may include field programmable gate array(s), and the destination(s) may include the general-purpose computing processor(s) or storage devices. The finite field arithmetic may include galois field arithmetic such as modular arithmetic, for example as may be used with respect to erasure coding for storage device(s). Aspects of a processing acceleration framework according to the subject technology also include associated methods.

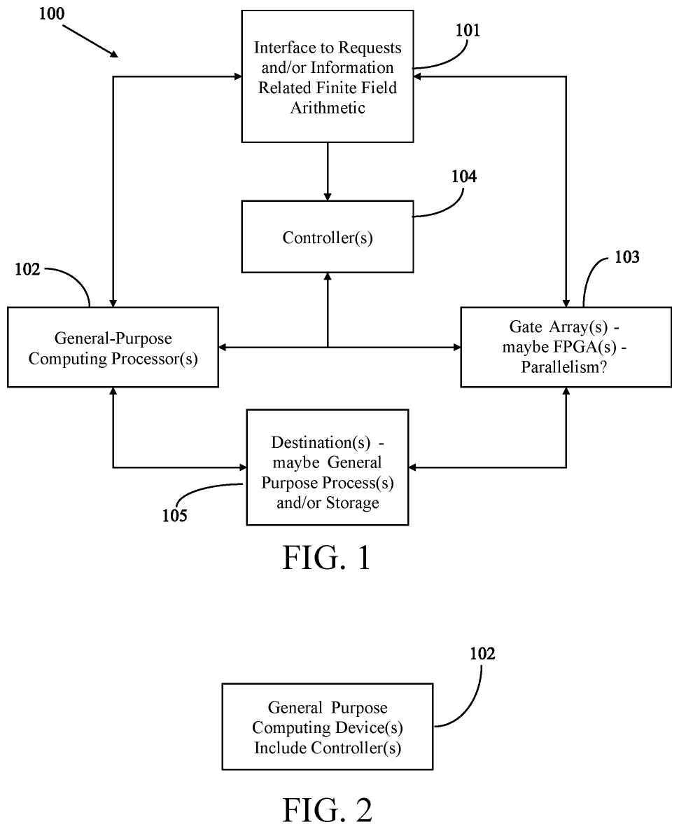

In more detail, FIG. 1 illustrates a processing acceleration system according to aspects of the subject technology. Processing acceleration system 100 shown in FIG. 1 includes interface 101 to requests or information. The requests may be related to certain operations, for example but not limited to finite field arithmetic. Examples of finite field arithmetic include Galois arithmetic and other modular arithmetic. Such arithmetic has many uses including but not limited to cryptography and data storage, for example erasure coding.

The information may be related to the requests, for example but not limited to information to be processed in accordance with the requests. For the sake of brevity, the term information as used herein may be or include the requests.

The information may be sent from interface 101 to general-purpose computing processor(s) 102 or gate array(s) 103 at the direction of controller(s) 104. In some aspects, controller(s) 104 determine that sending the information, performing the finite field arithmetic by gate array(s) 103, and sending results of the finite field arithmetic to at least one destination is more efficient than general-purpose computing processor(s) 102 performing the finite field arithmetic and sending the results to destination(s).

One possible reason that sending the information to gate array(s) 103 may be more efficient is gate array(s) are sometimes far more efficient at performing finite field arithmetic (e.g., modular addition, multiplication, subtraction, division, and greatest common divisor calculations) than general-purpose computing processor(s). For another example, many aspects of finite field arithmetic include many redundant calculations that can be more efficiently performed by gate array(s), for example in parallel.

In some aspects, gate array(s) 103 preferably are or include one or more field programmable gate arrays (FPGAs). Thus, these gate arrays may be updated to accommodate advances in certain implementations or applications of the relevant arithmetic without necessarily having to reprogram or otherwise modify the general-purpose computing processor(s).

FIG. 1 also shows destination(s) 105, for example general-purpose computing processor(s) 102. In some aspects, destination(s) 105 and general-purpose computing processors may be combined elements. Destination(s) 105 may also be one or more other elements such as storage.

The bi-directional arrows in FIG. 1 illustrate that the various elements may have two-way communications with each other. For example, some or all of the elements may provide information to other elements regarding current load, capacity, availability, or state. Controller(s) 104 may consider this information when determining where to perform or to send the information or results of the finite field arithmetic. The elements may also reject information, provide performance data, and otherwise interact to accelerate performance.

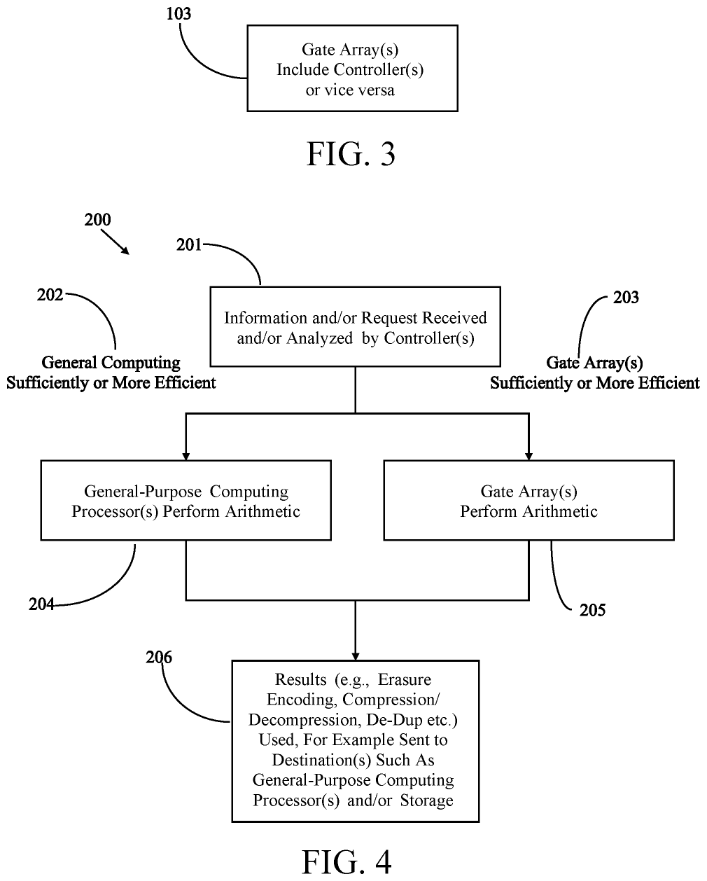

FIG. 2 illustrates that controller(s) used by aspects of the processing acceleration system may be physically included in general-purpose computing processor(s) 102. FIG. 3 illustrates that controller(s) used by aspects of the processing acceleration system may be physically included in gate array(s) 103. Other combinations are possible.

For example, general-purpose computing processor(s) 102 may physically include gate array(s) 103 such as FPGA(s). For another example, gate array(s) 103 may physically include general-purpose computing processor(s) 102. For yet another example, destination(s) 105 such as storage device(s) may physically include general-purpose computing processor(s) 102, gate array(s) 103, or some combination thereof. Thus, the elements illustrated in FIG. 1 are not necessarily intended to designate separate physical elements (e.g., devices or chip sets), but rather separate functional aspects of device(s).

FIG. 4 illustrates aspects of a method that may be used by a processing acceleration system according to aspects of the subject technology. The method includes steps that may be performed by performance acceleration system 100 or some other system.

In step 201, information or requests are received and analyzed by controller(s). Again for the sake of brevity, the term information as used herein may be or include the requests. This information preferably relates to finite field arithmetic.

Element 202 indicates the controller(s) determine that general-purpose computing processor(s) may be sufficiently capable of or more efficient at performing the requested finite field arithmetic. Element 203 indicates the controller(s) determine gate array(s) may be sufficiently capable of or more efficient at performing the requested finite field arithmetic. These determinations may involve information about the information as well as possibly from elements involved in the performance of the finite field arithmetic. Depending on the determinations, the information may be sent to either general-purpose computing device(s) or gate array(s) for performance of the arithmetic in steps 204 and 205 respectively. The results are used in step 206, for example sent to destination(s) such as general-purpose computing processor(s) or storage.

In some aspects, some or all of the information may be sent to both. For example, if both general-purpose computing processor(s) and gate array(s) are idle, the information may be sent to both in order to measure performance or to use results from whichever replies more efficiently.

As discussed above, one example application of the subject technology includes erasure coding. Such coding may include either or both encoding and decoding of erasure data.

One erasure coding scheme may defined as a K×N scheme where:
K is a number of data shards
N is a number of coding shards
original data to be saved is split into K data shards
each of those K shards is saved as the original data
additional shards are created by performing some encoding of the original data
if some of the K data shards are corrupted or lost, the N coding shards may be used to recover the original data

Many implementations of erasure coding involve various forms of finite field arithmetic that may be performed more efficiently by gate array(s) than general-purpose computing processor(s). In preferred aspects, encoding performed by general-purpose computing processor(s) may be decoded by gate array(s) and vice versa. The erasure coding by the general-purpose computing processor(s) preferably can use standard code bases for example but not limited to open source code bases. Performance of erasure coding therefore preferably may be accelerated without having to modify the code bases. In alternative aspects, modification of the code bases is possible or custom code bases may be used.

In one example, a hardware acceleration system 100 such as a module including interface 101 and gate array(s) 103 may be connected to general-purpose computing processor(s) 102 through a link such as a PCIe and to a network through an ethernet connector. Controller(s) 104 may reside in or on the hardware acceleration module, the general-purpose computing processor(s), or some other local or remote location. This implementation may allow off-loading of some task involved in erasure coding from the general-purpose computing processor(s) to the gate array(s), possibly freeing up the general computing processor(s) to perform operations for which they are more efficient.

Erasure coding in this example may be provided by a library called Jerasure using an algorithm called CRUSH (Controlled Replication Under Scalable Hashing) embodied in CEPH storage clusters. Gate array(s) 103 may be configured to perform such erasure coding more efficiently than general-purpose computing processor(s) 102. Jerasure encoding performed by gate array(s) 103 preferably may be decoded using general-purpose computing processor(s) 102 and vice versa, all without having to modify the underlying Jerasure library. Therefore, in preferred aspects, significant acceleration of performance may be achieved without a need to modify the Jerasure library.

Another example application of the subject technology includes other workloads such as compression/decompression and/or de-duplication (otherwise known as DeDup). The subject technology including use of gate array(s) 103 permit more efficient implementation of these applications.

The subject technology is not limited to the foregoing discussed form of erasure coding. Other forms of erasure coding, many cryptographic algorithms, and other algorithms involve finite field arithmetic. The subject technology may accelerate performance of these algorithms as well.

Some examples of such algorithms involve various forms of complimentary operations including but not limited to encoding and decoding, encrypting and decrypting, and creating hashes and validating hashes. Preferred aspects of the subject technology enable general-purpose computing processor(s) and gate array(s) to perform at least some of such complimentary operation(s) regardless of which one(s) perform others of such complimentary operation(s). Other examples of such algorithms involve non-complimentary operations, for example but not limited to greatest common divisor, factoring, checksum verification, and other algorithms.

The subject technology therefore may provide accelerated software and hardware performance involving various complimentary and non-complimentary algorithms, computations, processing, and the like. The accelerated performance may be achieved using open source code bases without a need to modify those code bases. In alternative aspects, the code bases may be modified or custom code bases may be used.

The subject technology may be performed by one or more computing device elements(s). The computing device(s) preferably includes at least a tangible computing element. Examples of a tangible computing element include but are not limited to a microprocessor, application specific integrated circuit, programmable gate array, memristor based device, and the like. A tangible computing element may operate in one or more of a digital, analog, electric, photonic, quantum mechanical, or some other manner. Control may be performed by a virtualized computing device that ultimately runs on tangible computing elements or any other form of computing device.

Additionally, some operations may be considered to be performed by multiple computing devices. For example, steps of controlling may be considered to be performed by both a local computing device and a remote computing device that instructs the local computing device to control something. Communication between computing devices may be through one or more other computing devices or networks.

The invention is in no way limited to the specifics of any particular aspects (e.g., embodiments, elements, steps, or examples) disclosed herein. For example, the terms “aspect,” “alternative,” “example,” “preferably,” “may,” “such as,” and the like denote features that may be preferable but not essential to include in some embodiments of the invention. The conjunctive “and” includes the disjunctive “or” and vice versa. Namely, “and” and “or” should be read as “and/or.”

Details illustrated or disclosed with respect to any one aspect of the invention may be used with other aspects of the invention. Additional elements or steps may be added to various aspects of the invention or some disclosed elements or steps may be subtracted from various aspects of the invention without departing from the scope of the invention. Singular elements/steps imply plural elements/steps and vice versa. Some steps may be performed serially, in parallel, in a pipelined manner, or in different orders than disclosed herein. Many other variations are possible which remain within the content, scope, and spirit of the invention, and these variations would become clear to those skilled in the art after perusal of this application.

What is claimed is:

1. A processing acceleration system comprising:
at least one gate array that performs finite field arithmetic; and
at least one controller that sends information to the at least one gate array upon a determination that sending the information, performing the finite field arithmetic by the at least one gate array, and sending results of the finite field arithmetic to at least one destination is more efficient than at least one general-purpose computing processor performing the finite field arithmetic and sending the results to the at least one destination.

2. The processing acceleration system as in claim 1, wherein the at least one gate array comprises at least one field programmable gate array.

3. The processing acceleration system as in claim 1, wherein the at least one gate array also assists with compression or decompression of data.

4. The processing acceleration system as in claim 1, wherein the at least one gate array also assists with de-deduplication of data.

5. The processing acceleration system as in claim 1, wherein the at least one destination comprises the at least one general-purpose computing processor, the at least one storage device, or some combination thereof.

6. The processing acceleration system as in claim 1, wherein the finite field arithmetic comprise galois field arithmetic.

7. The processing acceleration system as in claim 6, wherein the galois field arithmetic applies to erasure coding.

8. The processing acceleration system as in claim 1, wherein the finite field arithmetic comprises modular arithmetic.

9. The processing acceleration system as in claim 8, wherein the modular arithmetic applies to erasure coding.

10. The processing acceleration system as in claim 1, wherein the at least one controller comprises the at least one general-purpose computing processor.

11. The processing acceleration system as in claim 1, wherein the at least one controller comprises the at least one gate array.

12. The processing acceleration system as in claim 1, further comprising the at least one general-purpose computing processor.

13. A processing acceleration method comprising:
performing finite field arithmetic using at least one gate array;
sending, by at least one controller, information to the at least one gate array upon a determination that sending the information, performing the finite field arithmetic by the at least one gate array, and sending results of the finite field arithmetic to at least one destination is more efficient than at least one general-purpose computing processor performing the finite field arithmetic and sending the results to the at least one destination.

14. The processing acceleration method as in claim 13, wherein the at least one gate array comprises at least one field programmable gate array.

15. The processing acceleration method as in claim 13, wherein the at least one gate array also assists with compression or decompression of data.

16. The processing acceleration method as in claim 13, wherein the at least one gate array also assists with de-deduplication of data.

17. The processing acceleration method as in claim 13, wherein the at least one destination comprises the at least one general-purpose computing processor, the at least one storage device, or some combination thereof.

18. The processing acceleration method as in claim 13, wherein the finite field arithmetic comprise galois field arithmetic.

19. The processing acceleration method as in claim 18, wherein the galois field arithmetic applies to erasure coding.

20. The processing acceleration method as in claim 13, wherein the finite field arithmetic comprises modular arithmetic.

21. The processing acceleration method as in claim 20, wherein the modular arithmetic applies to erasure coding.

22. The processing acceleration method as in claim 13, wherein the at least one controller comprises the at least one general-purpose computing processor.

23. The processing acceleration method as in claim 13, wherein the at least one controller comprises the at least one gate array.
